(19) United States
(12) Patent Application Publication
(10) Pub. No.: US 2026/0353620 A1
(43) Pub. Date: Nov. 5, 2026

(54) POWER CONVERSION APPARATUS

(71) Applicant: Hyundai Kefico Corporation, Gunpo (KR)

(72) Inventors: Seung Hyuk Oh, Gunpo (KR); Chang Woo Seo, Gunpo (KR); Da Sook Kim, Gunpo (KR)

(21) Appl. No.: 19/726,315

(22) Filed: Jun. 30, 2026

Related U.S. Application Data
(63) Continuation of application No. PCT/KR2024/018611, filed on Nov. 22, 2024.

(30) Foreign Application Priority Data
Jan. 3, 2024 (KR) 10-2024-0000956

(51) Int. Cl. H05K 7/20; H02M 7/00; H05K 5/06; H05K 9/00

(52) U.S. Cl. CPC H05K 7/209; H02M 7/003; H05K 5/061; H05K 9/0037

(57) ABSTRACT

A power conversion apparatus for a vehicle according to an embodiment of the present invention comprises: a housing that houses and protects a plurality of power circuit boards and a control board; a main cooling flow path that is located at the bottom of the housing and has a main inlet and a main outlet for cooling water, the main inlet and the main outlet being located on one side and the other side of the housing, respectively; and a blocking plate that blocks electromagnetic interference between the plurality of power circuit boards and the control board arranged inside the housing. Here, the blocking plate is provided with a sub-cooling flow path connected to the main cooling flow path and radiates heat to a certain neighboring section.

### TECHNICAL FIELD

The present invention relates to a power conversion apparatus of a vehicle.

### BACKGROUND ART

A power conversion apparatus converts a general DC voltage into an AC voltage and then steps up or down the AC voltage using coils, transformers, capacitance, etc. Thereafter, the power conversion apparatus rectifies the AC voltage, rectifies the AC voltage back into a DC voltage, and supplies electricity according to voltages used in each electrical load.

According to the related art, since a cooling flow path is disposed on a bottom or side surface of a housing, a heat-generating element should be installed at a location at which the heat-generating element comes into surface contact with the cooling flow path. Accordingly, there is a problem of the arrangement of various parts being limited.

In addition, since a blocking plate is additionally installed to block electromagnetic interference between parts, the degree of freedom in internal package design is inevitably significantly reduced.

### DESCRIPTION OF INVENTION

### Technical Problem

The present invention is directed to solving the above-described problems and aims to provide a power conversion apparatus that secures design freedom and reduces production costs by integrating a cooling flow path with a blocking plate that blocks electromagnetic waves.

The problems to be solved by the present invention are not limited to those described above, and other problems not described above should be clearly understood by those skilled in the art from the following description.

### Technical Solution

A power conversion apparatus of a vehicle according to one embodiment of the present invention includes a housing configured to house and protect a plurality of power circuit boards and a control board, a main cooling flow path disposed at a lower end portion of the housing and having a main inlet and a main outlet of cooling water, which are located on one side and the other side of the housing, respectively, and a blocking plate configured to block electromagnetic interference between the plurality of power circuit boards and the control board, which are disposed inside the housing.

Here, the blocking plate may be provided with a sub-cooling flow path connected to the main cooling flow path and may dissipate heat of a certain neighboring section.

The blocking plate may include a first panel having a sealing groove recessed in a preset shape along an edge of a main body, a gasket forcibly fitted into the sealing groove, and a second panel connected to the first panel with the gasket interposed therebetween, wherein the sub-cooling flow path may be integrally formed on a main body of the second panel.

The blocking plate may be formed in a shape corresponding to the control board.

The blocking plate may seal an upper portion of the housing.

The main cooling flow path may be connected to the sub-cooling flow path located at an upper end thereof through one pipe.

The sub-cooling flow path has a linear structure with a constant cross-sectional area along a path thereof.

The sub-cooling flow path may be formed in a Venturi tube structure in which a cross-sectional area of a portion of a linear section along a path thereof decreases.

The sub-cooling flow path may have an S-shaped curve structure with a constant cross-sectional area along a path thereof.

The sub-cooling flow path may have a linear structure with a constant zigzag-shaped cross-sectional area along a path thereof.

The sub-cooling flow path may have inflection point sections at two or more points.

The sub-cooling flow path may have an inclination at a preset angle from a sub-inlet through which cooling water is introduced to a sub-outlet through which the cooling water is discharged.

The main cooling flow path may include a first connecting flow path configured to connect the main inlet to a sub-inlet of the sub-cooling flow path, and a second connecting flow path configured to connect the main outlet to a sub-outlet of the sub-cooling flow path.

The first and second connecting flow paths may have structures that are detachably attached to the sub-inlet and the sub-outlet respectively.

A cross-sectional area of the sub-inlet may be greater than or equal to a cross-sectional area of the sub-outlet.

The housing may have an open upper portion and an accommodation space therein and include an upper cover configured to cover the open upper portion of the housing, and a lower cover configured to cover a lower portion of the housing while surrounding the main cooling flow path.

The upper cover may include an upper cooling flow path connected to the main cooling flow path.

The upper cooling flow path may have a structure that is detachably attached to a lower end portion of the upper cover.

The housing may include hollow-shaped socket portions connected to the main cooling flow path.

The socket portion may be formed in connection structures that connect the sub-inlet of the sub-cooling flow path and the sub-outlet of the sub-cooling flow path to the main cooling flow path.

The socket portions may protrude in a preset section of the housing at intervals and may be inserted into and connected to the sub-inlet and the sub-outlet.

The socket portions may each include a connecting groove in which a portion of an end portion is recessed, and an elastic body forcibly fitted into the connecting groove to maintain sealing of a corresponding section.

### Advantageous Effects

In accordance with the present invention, there are effects as follows.

Design freedom can be secured by integrating a cooling flow path with a blocking plate that blocks electromagnetic waves.

Assembly costs can be minimized by reducing the number of parts, the degree of freedom in package configuration is increased, and thus an internal space of a housing can be easily used.

Heat dissipation performance can be improved by locating the existing limited cooling flow path inside the housing.

In particular, module integration is possible by stacking various boards inside the housing.

### DESCRIPTION OF DRAWINGS

FIG. 1 is a perspective view illustrating a power conversion apparatus according to one embodiment of the present invention.

FIG. 2 is a side view illustrating the power conversion apparatus according to one embodiment of the present invention.

FIG. 3 is an exploded perspective view illustrating the power conversion apparatus according to one embodiment of the present invention.

FIG. 4 is an exploded perspective view of a blocking plate according to one embodiment of the present invention.

FIG. 5 is a partial exemplary diagram illustrating a coupling relationship of portion A shown in FIG. 4.

FIG. 6 is an exemplary diagram illustrating a relationship between a main cooling flow path and a lower cover in the power conversion apparatus according to one embodiment of the present invention.

FIG. 7 is an exemplary plan view illustrating a configuration of the power conversion apparatus according to one embodiment of the present invention.

FIG. 8 is an exemplary bottom view illustrating a configuration of the power conversion apparatus according to one embodiment of the present invention.

FIG. 9 is an exemplary diagram illustrating a connection relationship between the blocking plate and the main cooling flow path according to one embodiment of the present invention.

FIG. 10 is an exemplary diagram illustrating a blocking plate according to another embodiment of the present invention.

FIG. 11 is a partial exemplary diagram illustrating a power conversion apparatus according to another embodiment of the present invention.

FIGS. 12 and 13 are exemplary diagrams illustrating a heat dissipation structure of the power conversion apparatus according to another embodiment of the present invention.

FIG. 14 is an exemplary diagram illustrating an application example of a blocking plate according to another embodiment of the present invention.

### MODES OF THE INVENTION

Advantages, features, and implementations of the present invention will be apparent from the embodiments which are described in detail below together with the accompanying drawings. However, the present invention is not limited to the exemplary embodiments described below and may be implemented in various other forms. The embodiments are provided such that this disclosure will be thorough and complete and will fully convey the scope of the present invention to those skilled in the art to which the present invention pertains, and the present invention is defined by only the description of the appended claims. Meanwhile, terms used herein are for the purpose of describing the embodiments and are not intended to limit the present invention. As used herein, singular forms include plural forms as well unless the context clearly indicates otherwise. The term “comprise” or “comprising” used herein does not preclude the presence or addition of one or more other elements, steps, operations, and/or devices other than stated elements, steps, operations, and/or devices. As used herein, the term “and/or” includes any one and all combinations of one or more listed items.

Hereinafter, exemplary embodiments of the present invention will be described in detail with reference to the accompanying drawings.

### Basic configuration

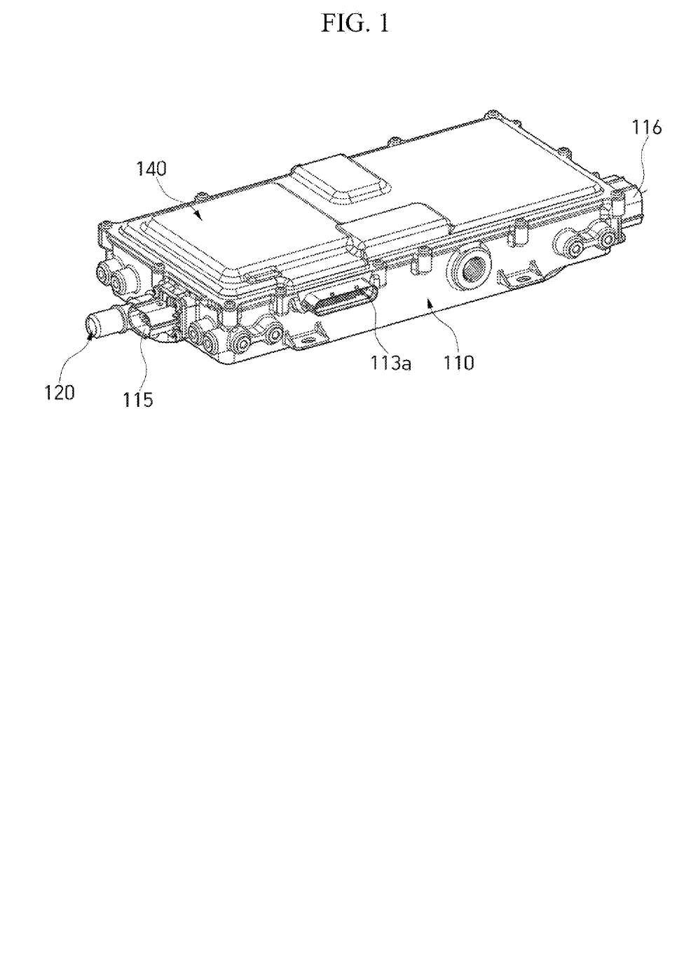

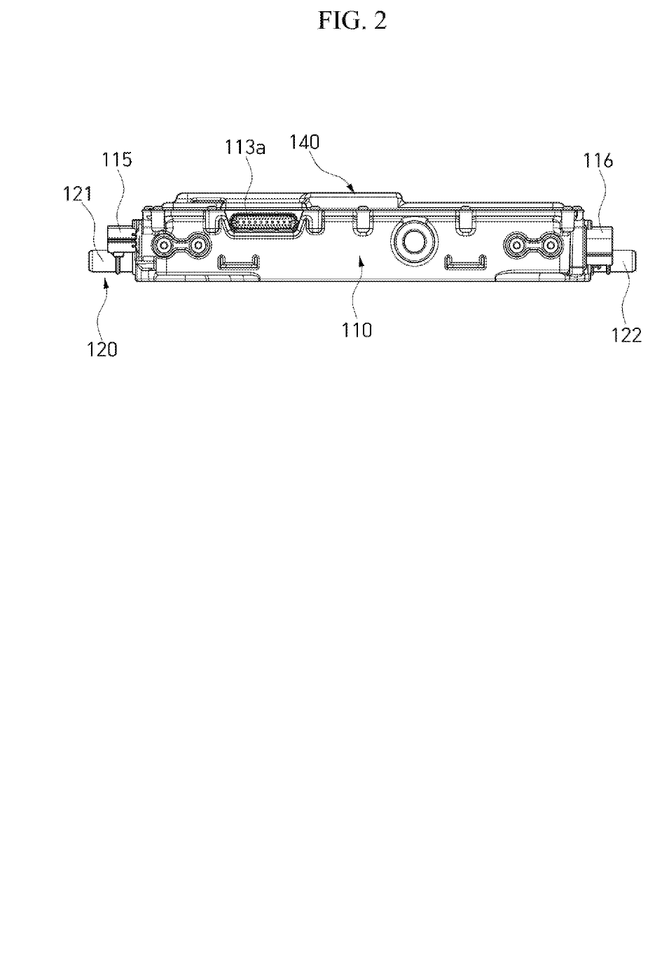

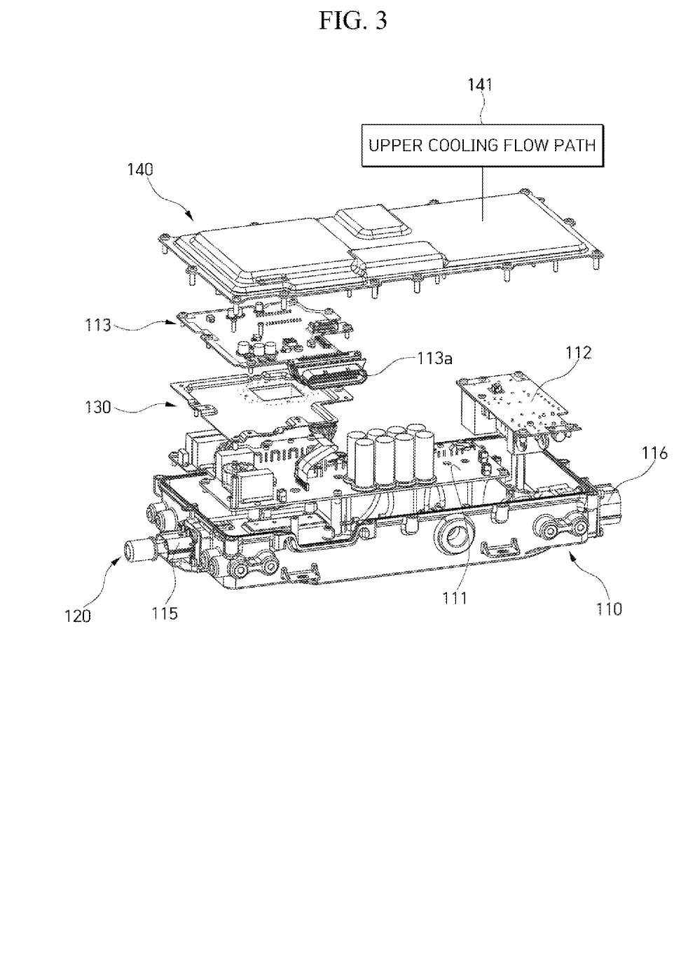

FIGS. 1 - 4 show a power conversion apparatus 100 and main components according to one embodiment of the present invention.

The power conversion apparatus 100 according to one embodiment of the present invention converts a general DC voltage into an AC voltage and steps up or down the AC voltage using coils, transformers, capacitance, etc. Thereafter, the power conversion apparatus serves to rectify the AC voltage back into a DC voltage and supply electricity according to voltages used in each electrical load.

The power conversion apparatus 100 according to one embodiment of the present invention has a main feature in which a blocking plate 130 has one cooling flow path to effectively dissipate the heat of internal components. Therefore, the remaining descriptions except for the portion related to the feature are omitted, but even when the remaining descriptions are omitted, the power conversion apparatus 100 may include necessary components and functions.

The power conversion apparatus 100 according to one embodiment of the present invention includes a housing 110, a main cooling flow path 120, a blocking plate 130, and an upper cover 140.

The housing 110 has an open upper portion and an accommodation space therein. The housing 110 accommodates and protects a plurality of power circuit boards 111 and 112 and a control board 113 in the accommodation space.

The main cooling flow path 120 is disposed at a lower end portion of the housing 110.

The main cooling flow path 120 includes a main inlet 121 located on one side of the housing 110, a main outlet 122 located on the other side of the housing 110, a first connecting flow path 123, and a second connecting flow path 124.

The blocking plate 130 blocks electromagnetic interference between the plurality of power circuit boards 111 and 112 and the control board 113, which are disposed in the housing 110.

In addition, the blocking plate 130 may dissipate the heat of a certain neighboring section connected to the main cooling flow path 120.

The blocking plate 130 may be formed in a shape corresponding to the control board 113 in order to effectively block electromagnetic waves and dissipate heat to the surroundings.

The blocking plate 130 includes a first panel 131, a gasket 132, and a second panel 133.

The first panel 131 includes a sealing groove 131a that is recessed in a predetermined shape along an edge of a main body. Here, the predetermined shape may be different depending on the location of neighboring electronic components.

The gasket 132 functions as a packing member that is forcibly fitted into the sealing groove 131a. The gasket 132 may be made of a rubber material. The gasket 132 may have a structure in which a plurality of protrusions (not shown) or grooves (not shown) are formed at each connection section with the sealing groove 131a. In this case, separate protrusions (not shown) corresponding to the grooves of the gasket 132 may be formed at intervals on the sealing groove 131a.

The second panel 133 is coupled to the first panel 131 with the gasket 132 interposed therebetween. The second panel 133 is formed integrally with a sub-cooling flow path 133a connected to the main cooling flow path 120 on the main body. The main cooling flow path 120 may be connected to the sub-cooling flow path 133a located at an upper end through one pipe.

The sub-cooling flow path 133a may have an S-shaped curve structure with a constant cross-sectional area along a path thereof.

As another example, the sub-cooling flow path 133a may have a zigzag structure with a constant cross-sectional area along the path thereof. In this case, the sub-cooling flow path 133a may have an inflection point section at two or more points.

The upper cover 140 covers the open upper surface of the housing 110. In this case, the upper cover 140 may include an upper cooling flow path 141 connected to the main cooling flow path 120.

The upper cooling flow path 141 may have a structure detachably attached to a lower end portion of the upper cover 140. The upper cooling flow path 141, the main cooling flow path 120, and the sub-cooling flow path 133a of the blocking plate 130 may also be connected through one pipe.

### Structure and connection relationship of cooling flow path

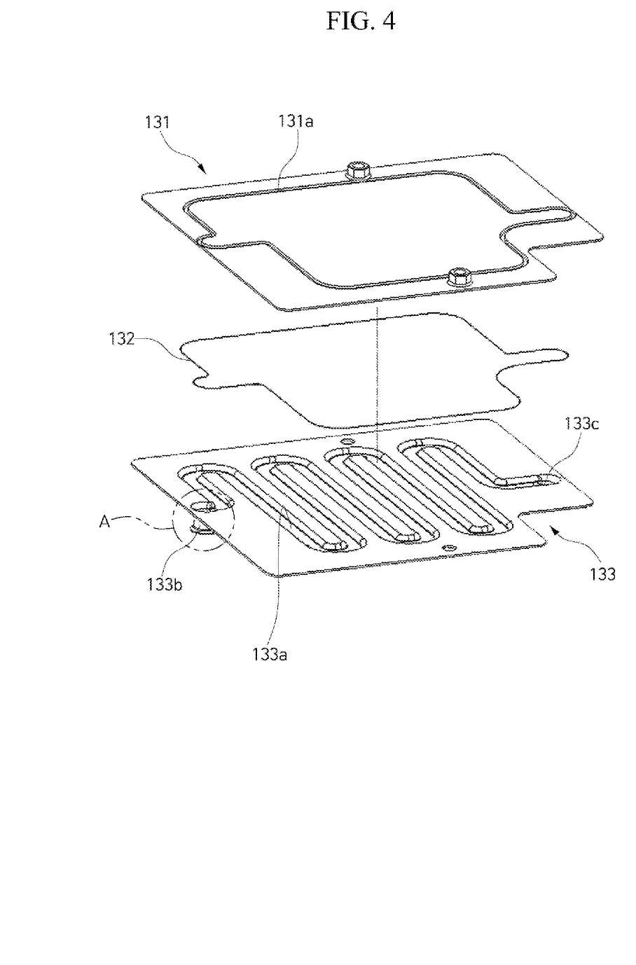

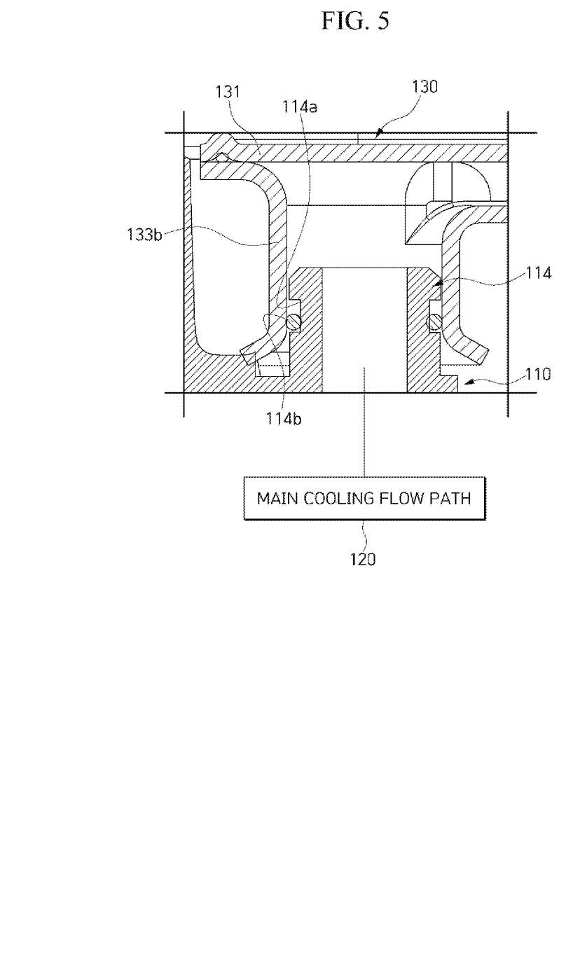

FIG. 5 shows a coupling relationship of portion A shown in FIG. 4.

The housing 110 includes hollow-shaped socket portions 114 that are connected to the main cooling flow path 120. In this case, two or more socket portions 114 may be formed on the main body of the housing 110.

The socket portions 114 may be connection structures that connect a sub-inlet 133b of a sub-cooling flow path 133a (see FIG. 4) and a sub-outlet 133c (see FIG. 4) of the sub-cooling flow path 133a (see FIG. 4) to the main cooling flow path 120.

The socket portions 114 protrude at intervals in a preset section of the housing 110 and has structures that are inserted into and connected to the sub-inlet 133b and the sub-outlet 133c (see FIG. 4).

Each of the socket portions 114 includes a connecting groove 114a and an elastic body 114b.

The connecting groove 114a has a structure in which a portion of an end portion of the socket portion 114 is recessed.

The elastic body 114b is forcibly fitted into the connecting groove 114a and serves to maintain the sealing of a corresponding section.

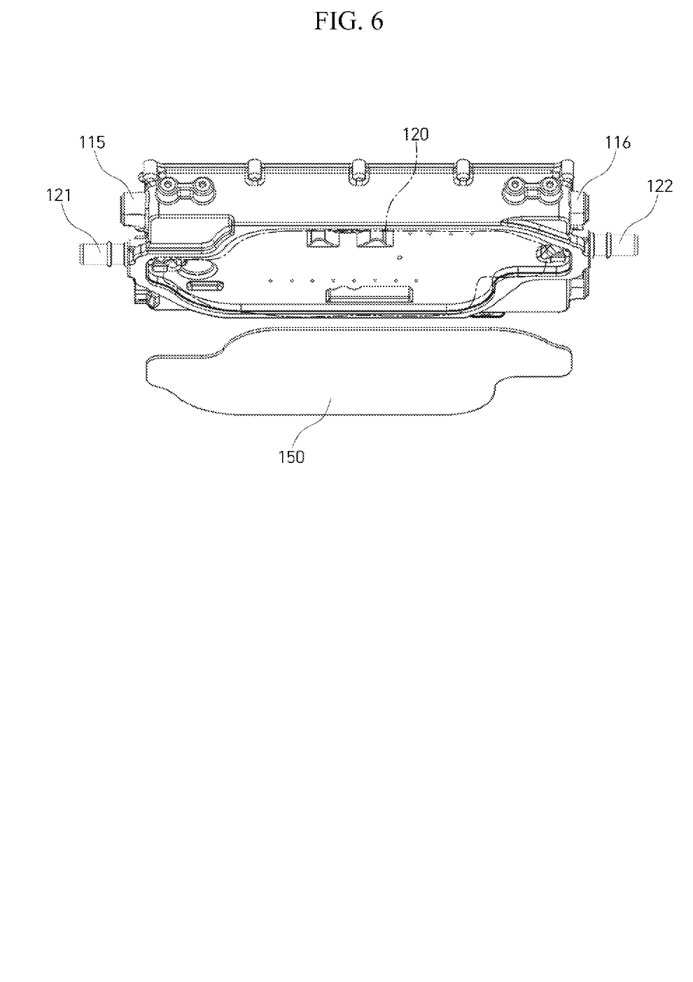

FIG. 6 shows a relationship between a main cooling flow path and a lower cover in the power conversion apparatus according to one embodiment of the present invention.

A lower cover 150 covers a lower portion of the housing 110 while surrounding the main cooling flow path 120. In this case, the lower cover 150 may be connected to the housing 110 in a snap-fit fastening structure or may be detachably fastened to the housing 110 in a sliding insertion manner.

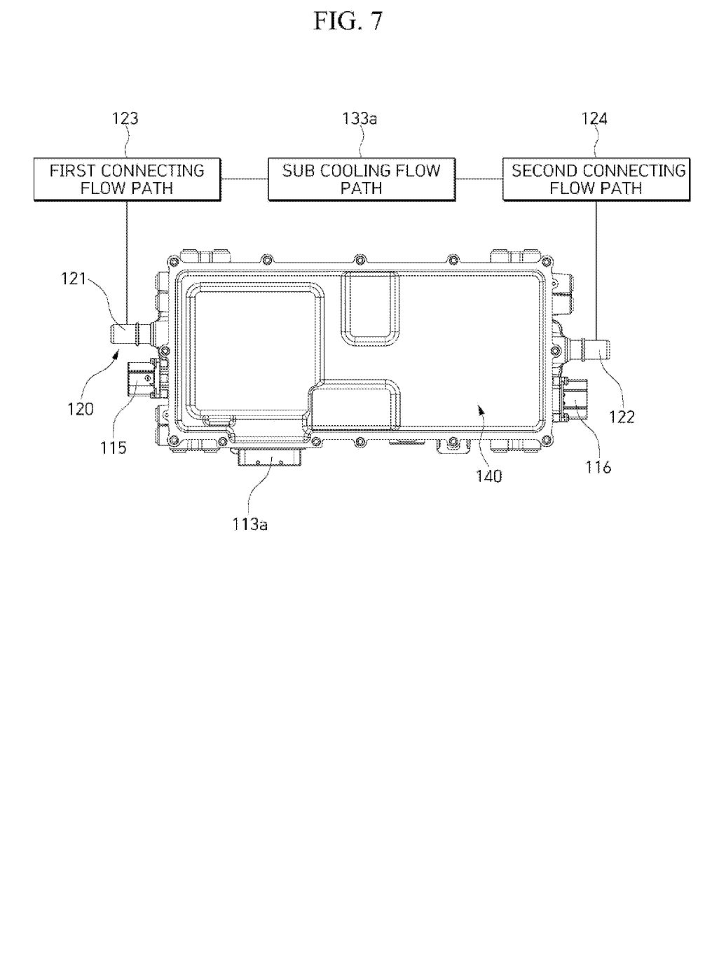

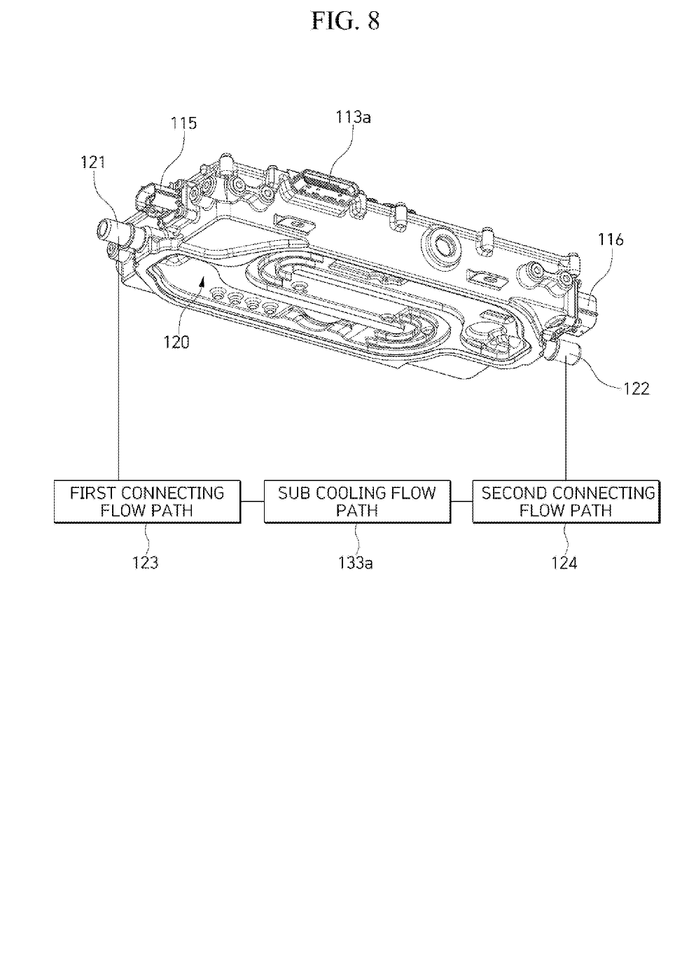

FIGS. 7 and 8 show a structure of the cooling flow path of the power conversion apparatus according to one embodiment of the present invention.

The main cooling flow path 120 and the sub-cooling flow path 133a may be located between upper and lower boards for managing the heat generation of the upper and lower boards embedded in the housing of the power conversion apparatus 100.

The sub-cooling flow path 133a is formed between the boards inside the housing and performs heat dissipation. In this case, the main cooling flow path 120 and the sub-cooling flow path 133a are connected through one pipe. That is, the one pipe may have a structure in which cooling water may flow along the main inlet 121 and join the main outlet 122 via the sub-cooling flow path 133a.

The first connecting flow path 123 connects the main inlet 121 to the sub-inlet 133b of the sub-cooling flow path 133a (see FIG. 4).

The second connecting flow path 124 connects the main outlet 122 to the sub-outlet 133c of the sub-cooling flow path 133a (see FIG. 4).

The first and second connecting flow paths 123 and 124 may have structures that are detachably attached to the sub-inlet 133b (see FIG. 4) and the sub-outlet 133c (see FIG. 4), respectively.

Here, although the first and second connecting flow paths 123 and 124 have the same connection structure and purpose as those of the socket portion 114 of FIG. 5, the first and second connecting flow paths 123 and 124 may be configured as a separate structure or may perform the role of a connector that connects the socket portion 114 to the sub-inlet 133b.

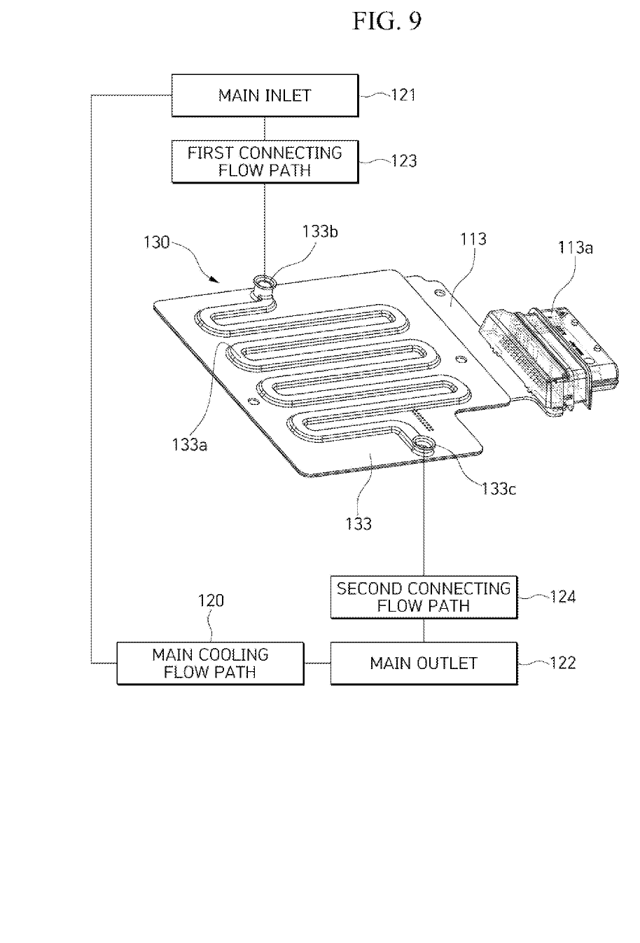

FIG. 9 shows a connection relationship between the blocking plate and the main cooling flow path according to one embodiment of the present invention.

The main cooling flow path 120 may be connected to the sub-cooling flow path 133a located at the upper end through one pipe.

The sub-cooling flow path 133a may be formed in a Venturi tube structure in which a cross-sectional area of a portion of a linear section along the path thereof decreases. As another example, the sub-cooling flow path 133a may have a linear structure with a constant cross-sectional area along the path thereof.

The sub-cooling flow path 133a may have an inclination at a preset angle from the sub-inlet 133b through which cooling water is introduced to the sub-outlet 133c through which the cooling water is discharged.

The cross-sectional area of the sub-inlet 133b may be greater than or equal to the cross-sectional area of the sub-outlet 133c to compensate for a flow rate of the cooling water. This allows cooling water of the main cooling flow path 120 and the sub-cooling flow path 133a to join smoothly.

Meanwhile, the connector 113a is mounted on a lower portion of the control board 113. In this case, the connector 113a is preferably surface-mounted on the control board 113.

The blocking plate 130 may be soldered to the control board 113 on which the connector 113a is mounted.

### Modified examples

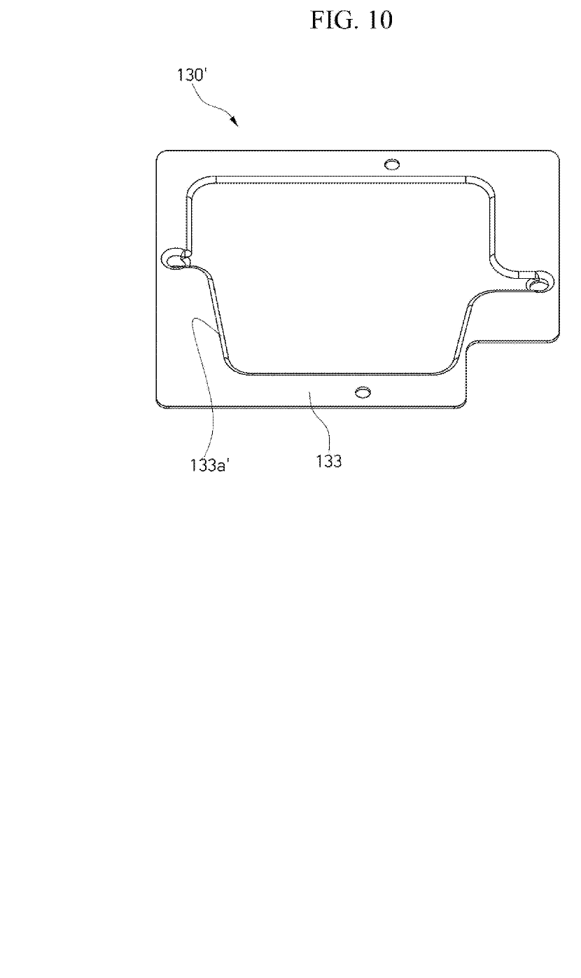

FIG. 10 shows a blocking plate according to another embodiment of the present invention.

A blocking plate 130’ may suppress the pressure loss of cooling water by applying a sub-cooling flow path 133a’ in a linear structure.

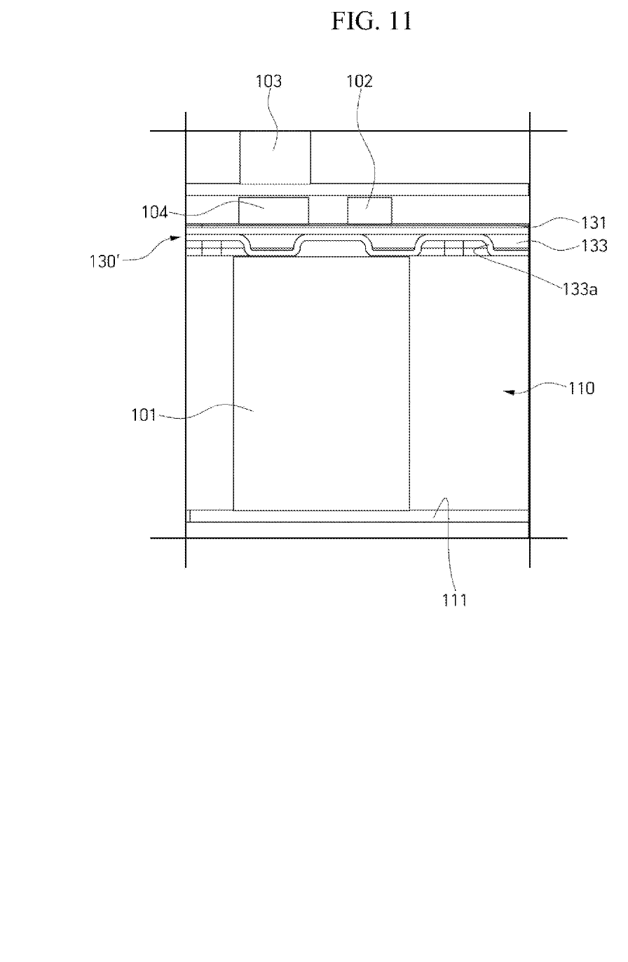

FIG. 11 shows a modified heat dissipation structure of the power conversion apparatus according to another embodiment of the present invention.

The blocking plate 130’ dissipates heat from an upper surface of a first heat-generating element 101 of a first power circuit board 111 located below.

A heat-dissipating material 104 may be mounted on an upper portion of the first panel 131 to dissipate heat from a third heat-generating element 103 located at an upper end.

A second heat-generating element 102 is mounted on a lower portion of the upper board, and its heat may be dissipated by the blocking plate 130’.

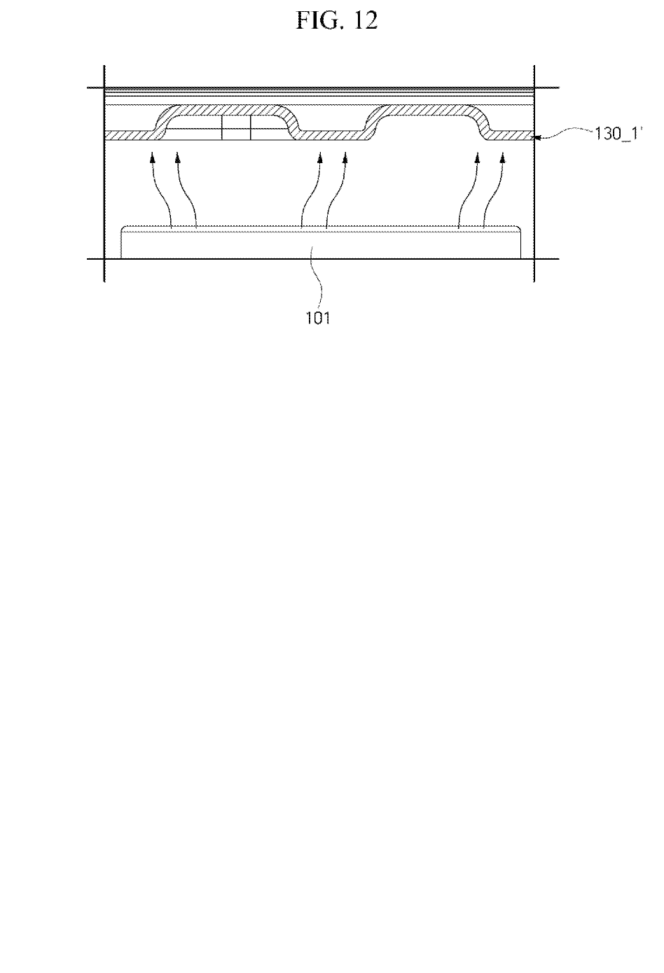

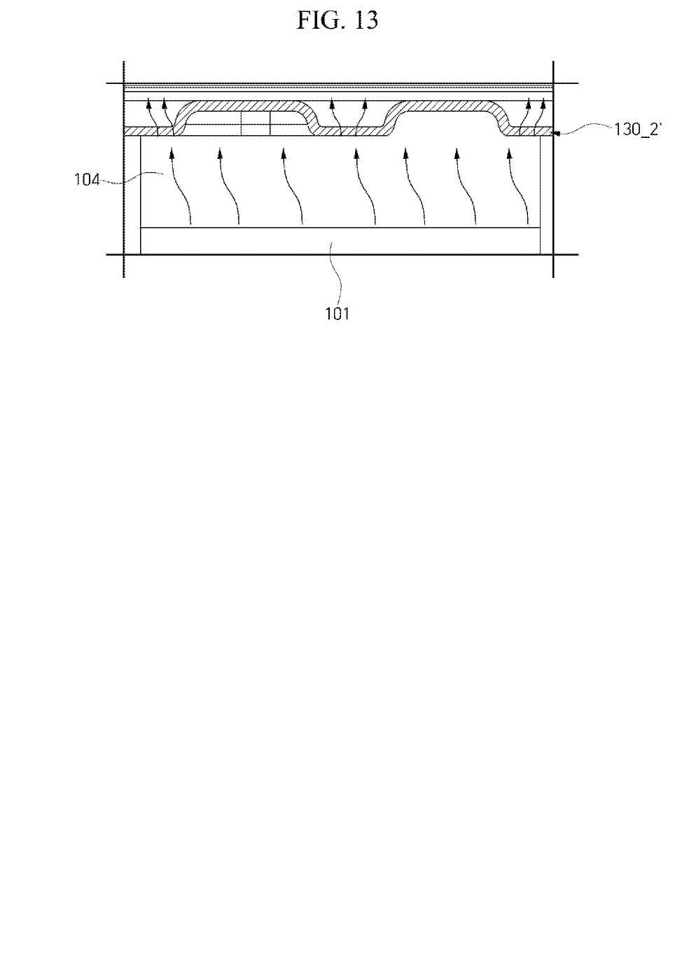

FIGS. 12 and 13 show a heat dissipation structure of the power conversion apparatus according to another embodiment of the present invention.

In FIG. 12, the heat of the first heat-generating element 101 may be dissipated through natural convection of a blocking plate 130_1’.

In FIG. 13, the first heat-generating element 101 faces the blocking plate 130_2’ with the heat-dissipating material 104 interposed therebetween. The heat-dissipating material 104 is located between the first heat-generating element 101 and the blocking plate 130_2’ and dissipates heat to the surroundings. Heat dissipation performance may be improved by adding the heat-dissipating material 104.

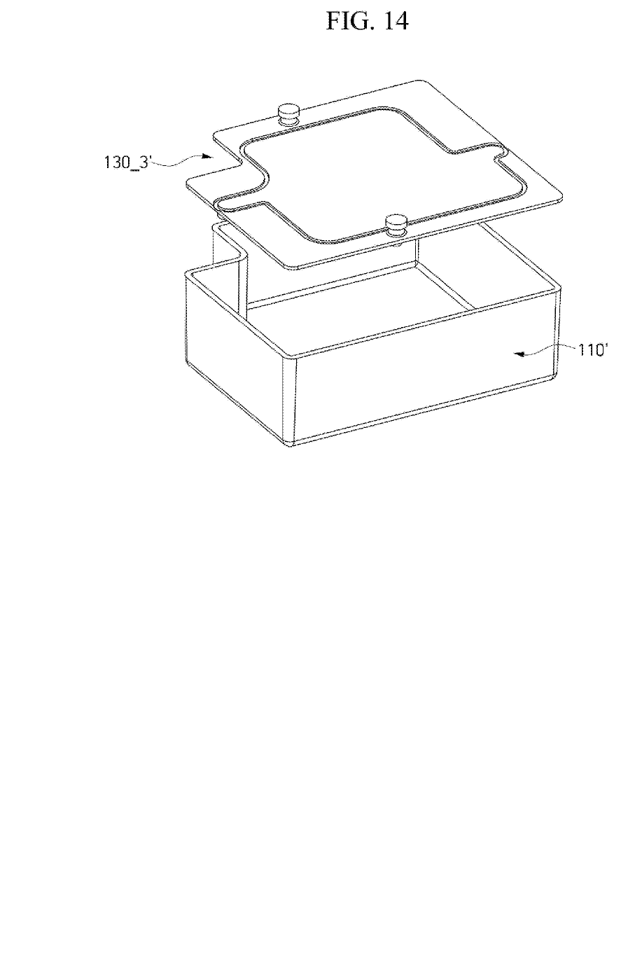

FIG. 14 shows an application example of a blocking plate according to another embodiment of the present invention.

A blocking plate 130_3’ may also perform the role of sealing an open upper portion of a housing 110’. In this case, the blocking plate 130_3’ may not only provide cooling performance but also serve as an upper cover.

Although the configuration of the present invention has been described in detail through the exemplary embodiments, this is merely an example, and various modifications and changes are possible within the scope permitted by the technical idea of the present invention.

Therefore, the technical scope of the present invention should be defined by the appended claims.

1. A power conversion apparatus of a vehicle, comprising:
a housing configured to house and protect a plurality of power circuit boards and a control board;
a main cooling flow path disposed at a lower end portion of the housing and having a main inlet and a main outlet of cooling water, which are located on one side and the other side of the housing, respectively; and
a blocking plate configured to block electromagnetic interference between the plurality of power circuit boards and the control board, which are disposed inside the housing,
wherein the blocking plate is provided with a sub-cooling flow path connected to the main cooling flow path and dissipates heat of a certain neighboring section.

2. The power conversion apparatus of claim 1, wherein the blocking plate includes:
a first panel having a sealing groove recessed in a preset shape along an edge of a main body;
a gasket forcibly fitted into the sealing groove; and
a second panel connected to the first panel with the gasket interposed therebetween,
wherein the sub-cooling flow path is integrally formed on a main body of the second panel.

3. The power conversion apparatus of claim 1, wherein the blocking plate is formed in a shape corresponding to the control board.

4. The power conversion apparatus of claim 1, wherein the blocking plate seals an upper portion of the housing.

5. The power conversion apparatus of claim 1, wherein the main cooling flow path is connected to the sub-cooling flow path located at an upper end thereof through one pipe.

6. The power conversion apparatus of claim 5, wherein the sub-cooling flow path has a linear structure with a constant cross-sectional area along a path thereof.

7. The power conversion apparatus of claim 5, wherein the sub-cooling flow path is formed in a Venturi tube structure in which a cross-sectional area of a portion of a linear section along a path thereof decreases.

8. The power conversion apparatus of claim 5, wherein the sub-cooling flow path has a linear structure with a constant S-shaped cross-sectional area along a path thereof.

9. The power conversion apparatus of claim 5, wherein the sub-cooling flow path has a linear structure with a constant zigzag-shaped cross-sectional area along a path thereof.

10. The power conversion apparatus of claim 9, wherein the sub-cooling flow path has inflection point sections at two or more points.

11. The power conversion apparatus of claim 5, wherein the sub-cooling flow path has an inclination at a preset angle from a sub-inlet through which cooling water is introduced to a sub-outlet through which the cooling water is discharged.

12. The power conversion apparatus of claim 1, wherein the main cooling flow path includes:
a first connecting flow path configured to connect the main inlet to a sub-inlet of the sub-cooling flow path; and
a second connecting flow path configured to connect the main outlet to a sub-outlet of the sub-cooling flow path.

13. The power conversion apparatus of claim 12, wherein the first and second connecting flow paths have structures that are detachably attached to the sub-inlet and the sub-outlet, respectively.

14. The power conversion apparatus of claim 12, wherein a cross-sectional area of the sub-inlet is greater than or equal to a cross-sectional area of the sub-outlet.

15. The power conversion apparatus of claim 1, wherein:
the housing has an open upper portion and an accommodation space therein;
an upper cover configured to cover the open upper portion of the housing; and
a lower cover configured to cover a lower portion of the housing while surrounding the main cooling flow path.

16. The power conversion apparatus of claim 15, wherein the upper cover includes an upper cooling flow path connected to the main cooling flow path.

17. The power conversion apparatus of claim 16, wherein the upper cooling flow path has a structure that is detachably attached to a lower end portion of the upper cover.

18. The power conversion apparatus of claim 1, wherein:
the housing includes hollow-shaped socket portions connected to the main cooling flow path; and
the socket portions are formed in connection structures that connect a sub-inlet of the sub-cooling flow path and a sub-outlet of the sub-cooling flow path to the main cooling flow path.

19. The power conversion apparatus of claim 1, wherein the socket portions protrude in a preset section of the housing at intervals and are inserted into and connected to a sub-inlet and a sub-outlet.

20. The power conversion apparatus of claim 1, wherein each of the socket portions includes:
a connecting groove in which a portion of an end portion is recessed; and
an elastic body forcibly fitted into the connecting groove to maintain sealing of a corresponding section.
